(19) United States
(12) Patent Application Publication
(10) Pub. No.: US 2009/0153130 A1
(43) Pub. Date: Jun. 18, 2009

(54) FIELD EFFECT TRANSISTOR-BASED BIOSENSOR WITH INORGANIC FILM, METHOD OF MANUFACTURING THE BIOSENSOR, AND METHOD OF DETECTING BIOMOLECULE USING THE BIOSENSOR

(75) Inventors: Jeo-young SHIM, Yongin-si (KR); Kyu-sang LEE, Suwon-si (KR); Chang-eun YOO, Seoul (KR); Kyu-youn HWANG, Incheon-si (KR); Young-a KIM, Suwon-si (KR); Kyu-tae YOO, Seongnam-si (KR); Yeon-ja CHO, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/556,783

(22) Filed: Nov. 6, 2006

(30) Foreign Application Priority Data
Nov. 22, 2005 (KR) 10-2005-0111975

(51) Int. Cl. G01N 27/00; H01L 29/772; H01L 21/335

(52) U.S. Cl. 324/72; 257/253; 438/49; 257/E29.242; 257/E21.4

(57) ABSTRACT

Provided is a Field-Effect Transistor (FET)-based biosensor including: a substrate; a source and a drain, disposed on the substrate, having opposite polarity to the substrate; a gate, disposed on the substrate, contacting the source and the drain; and an inorganic film capable of binding with a biomolecule, disposed on a surface of the gate. A method of manufacturing the FET-based biosensor and a method of detecting a biomolecule using the FET-based biosensor is also provided. The FET-based biosensor can be manufactured using a semiconductor fabrication process without performing an additional process. Therefore, the inorganic film can be selectively deposited on a surface of a specific gate of a single FET, or on the surfaces of some gates of a plurality of FETs using patterning. Furthermore, the FET-based biosensor can be used to effectively detect trace amounts of a target biomolecule in a sample.

### CROSS-REFERENCE TO RELATED PATENT APPLICATION

This application claims priority to Korean Patent Application No. 10-2005-0111975, filed on Nov. 22, 2005, in the Korean Intellectual Property Office, and all the benefits accruing therefrom under 35 U.S.C. §119, the disclosure of which is incorporated herein in its entirety by reference.

### BACKGROUND

1. Field of the Invention

The present invention relates to a Field-Effect Transistor (FET)-based biosensor comprising source, gate, and drain electrodes, a method of manufacturing a FET-based biosensor and a method for determining the presence or concentration of a biomolecule using a FET-based biosensor.

2. Description of the Related Art

Among biomolecule detection sensors using electrical signals, there are transistor-based biosensors. Transistor-based biosensors are manufactured using a semiconductor process. Advantages of transistor-based biosensors are allowing for the rapid transformation of biological events into electrical signals and easy combination with Integrated Circuit (IC) technology and/or the Micro-Electro-Mechanical System (MEMS) technology. Thus, there has been much research into transistor-based biosensors in recent years.

A biosensor for detecting biological events using a Field Effect Transistor (FET) was first reported in U.S. Pat. No. 4,238,757. U.S. Pat. No. 4,238,757 disclosed a FET comprising a layer of protein consisting of antibodies specific to a particular antigen. According to the disclosure, addition of a solution containing the particular antigen to the FET results in change in the surface charge concentration due to the antigen-antibody reaction, thereby affecting the charge concentration in the semiconductor inversion layer. The change in charge concentration can be detected by measuring a change in current. U.S. Pat. No. 4,777,019 also discloses a FET biosensor. For the biosensor disclosed in U.S. Pat. No. 4,777,019, biological monomers are adsorbed to a surface of a gate. The biosensor can then be used to detect biological monomers that are complementary to the biological monomers adsorbed to the surface of the gate. The degree of hybridization of the adsorbed biological monomers with their complementary monomers is measured using the FET.

U.S. Pat. No. 5,846,708 discloses an optical method of detecting hybridization events using a Charged Coupled Device (CCD) based on light absorption by bound biomolecules. U.S. Pat. Nos. 5,466,348 and 6,203,981 disclose a method and a device for enhancing the signal-to-noise ratio using a combination of a Thin Film Transistor (TFT) with a circuit.

As described above, FET-based biosensors save costs and time relative to conventional biosensors, and are easily combined with IC technology and MEMS technology.

FIG. 1A is a schematic diagram showing the structure of a conventional FET. Referring to FIG. 1A, a source 12a and a drain 12b are respectively disposed in separated regions of a substrate 11. The source 12a and the drain 12b are doped with an n- or p-type impurity to have polarity opposite to that of the substrate 11. A gate 13 contacting the source 12a and the drain 12b is disposed on the substrate 11. Generally, the gate 13 is composed of an oxide layer 14, a polysilicone layer 15, and a gate electrode layer 16. A probe biomolecule is attached onto the gate electrode layer 16.

FIG. 1B is a schematic diagram illustrating binding of a target biomolecule to a probe biomolecule 18 immobilized on a surface of a gate electrode 16. The probe biomolecule binds with a target biomolecule via, for example, a hydrogen bond, etc., and the binding between the probe biomolecule and the target biomolecule 18 is measured by an electrical method. Referring to FIG. 1B, the intensity of a current in the channel changes according to whether the immobilized probe biomolecule 18 on the surface of the gate electrode 16 remains unbound, as compared to when the target biomolecule is bound to the immobilized probe biomolecule 18. Thus, the target biomolecule can be detected based on the change in current.

Microarray techniques for immobilizing a biomolecule, such as an oligonucleotide or a PCR product, on a surface of a gate electrode are known in the art. However, application of the microarray technique to a FET-based sensor is limited since it is difficult to detect a hybridization event at a distance from the gate surface greater than the Debye length.

Further, methods of depositing an organic film on the surface of the gate electrode have been utilized for immobilizing a biomolecule on a surface of a gate electrode. For example, WO 2004/057027 discloses the immobilization of a biomolecule on a surface of a gate electrode, including depositing positively charged Poly-L-Lysine (PLL) on a surface of the gate electrode using a wet process, spotting DNAs on a surface of the PLL coating using a spotter, and measuring a voltage difference before and after the spotting.

However, the method of WO 2004/057027 requires a separate wet process after FET fabrication, and thus, does not permit patterning, which makes it difficult to selectively deposit PLL on a surface of the gate electrode. For this reason, it is impossible to manufacture a reference FET in which no biomolecule, e.g., DNA, has been immobilized. Further, an additional drawback is that a large number of biomolecules are necessary for probe biomolecule immobilization or target biomolecule binding to the immobilized probes. Furthermore, since the organic film is generally made of a positively charged polymer, it is difficult to control the thickness of the organic film. Thus, the thickness of the organic film may be greater than the Debye length, which is defined as the detectable limit of a FET. In addition, it is difficult to apply the spotting technique for DNA immobilization to a lab-on-a-chip.

Additionally, in other conventional FET biosensors, single-stranded probe nucleic acids are immobilized on a surface of a gate via a covalent bond, and single-stranded target nucleic acids complementary to the probe nucleic acids are hybridized to the probe nucleic acids on the surface of the gate. However, probe immobilization and hybridization in a solution are very time consuming. In addition, in view of the Debye length, a FET requires a low ion concentration to detect a signal and under such conditions it is difficult to efficiently carry out hybridization.

### SUMMARY OF THE INVENTION

In one embodiment, the invention provides a Field-Effect Transistor (FET)-based biosensor comprising an inorganic film. The inorganic film can be selectively deposited on a surface of a gate of a single FET. For a plurality of FETs, the inorganic film can be selectively deposited on a surface of some of the gates using a semiconductor fabrication process.

In one embodiment, the invention provides a FET-based biosensor comprising: a substrate; a source and a drain, wherein the source and the drain are disposed on separated regions of the substrate, wherein polarity of the source and the drain is opposite to polarity of the substrate; a gate, disposed on the substrate, wherein the gate contacts the source and the drain; and an inorganic film disposed on a surface of the gate, wherein the inorganic film is capable of binding with a biomolecule.

In another embodiment, the invention provides a method of manufacturing a FET-based biosensor, the method comprising: exposing a gate electrode of a FET; and depositing an inorganic film.

In another embodiment, the invention provides a method of detecting a biomolecule, the method comprising: introducing a biomolecule to a surface of a gate of a FET-based biosensor, wherein an inorganic film capable of binding with the biomolecule is disposed on the surface of the gate; and measuring a current in a channel region between a source and a drain of the FET-based biosensor before and after introducing the biomolecule.

According to the invention, even a trace of a target biomolecule can be effectively detected. In addition, since the inorganic film can be formed to a very thin thickness, the binding of a biomolecule to the inorganic film can be detected within the detectable limit (Debye length) of the FET.

### BRIEF DESCRIPTION OF THE DRAWINGS

FIG. 1A is a schematic diagram showing the structure of a conventional Field-Effect Transistor (FET);

FIG. 1B is a schematic diagram illustrating the binding of a target biomolecule to a probe biomolecule immobilized on a surface of a gate electrode of the FET of FIG. 1A;

FIG. 2 is a schematic diagram showing the structure of an exemplary embodiment of a FET-based biosensor according to the invention;

FIG. 3 is a schematic diagram showing the sequential processes for manufacturing a FET-based biosensor according to the invention;

FIG. 4A is an image showing aluminum (Al) deposited on a surface of a gate in a FET-based biosensor according to the invention;

FIG. 4B is an image showing porous boehmite produced when the aluminum deposited on the surface of a gate, as shown in FIG. 4A, is treated with hot water;

FIG. 5 is a graph illustrating a change in current when oligonucleotide and poly-L-lysine are alternately loaded onto a surface of a gate in a FET-based biosensor according to the invention;

FIG. 6 is a graph showing the change in current when a Polymerase Chain Reaction (PCR) product and poly-L-lysine are alternately loaded onto a surface of a gate in a FET-based biosensor according to the invention; and

FIG. 7 is a graph showing the change in current when a Non-Template Control (NTC, negative control) product and poly-L-lysine are alternately loaded onto a surface of a gate in a FET-based biosensor according to the invention.

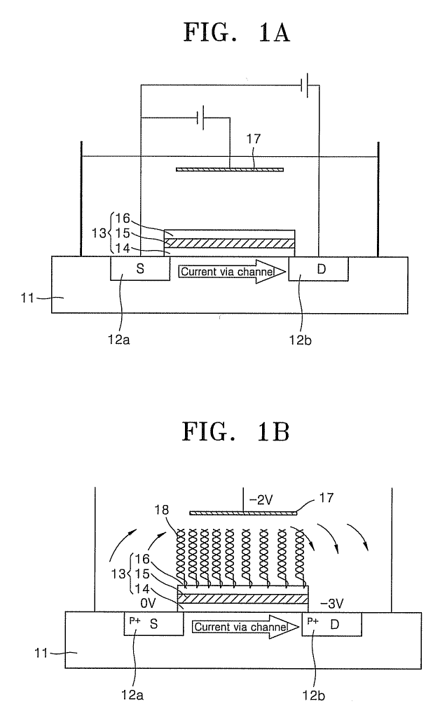

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In one embodiment, the invention provides a Field-Effect Transistor (FET)-based biosensor wherein an inorganic film capable of binding with a biomolecule is disposed on a surface of a gate.

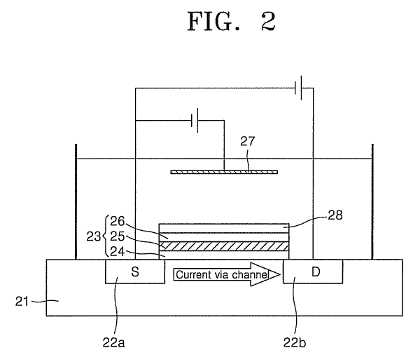

FIG. 2 is a schematic diagram showing the structure of an exemplary embodiment of a FET-based biosensor according to the invention.

Referring to FIG. 2, the exemplary FET-based biosensor includes a substrate 21; a source 22a and a drain 22b, respectively disposed in separated regions of the substrate 21 and having opposite polarity to the substrate 21; a gate 23, disposed on the substrate 21, contacting the source 22a and the drain 22b; and an inorganic film 28 disposed on a surface of the gate 23. The inorganic film is capable of binding with a biomolecule.

As used herein, a FET may be any FET used in conventional biosensors, Complementary Metal Oxide Semiconductor (CMOS) devices, and the like. The FET may be n-MOS or p-MOS. For example, when the substrate 21 is doped with n-type impurity, the source 22a and the drain 22b can be doped with p-type impurity. On the other hand, when the substrate 21 is doped with p-type impurity, the source 22a and the drain 22b can be doped with n-type impurity.

In one embodiment, the source 22a of the FET supplies carriers, e.g., free electrons or holes, to the drain 22b, the drain 22b receives the carriers from the source 22a, and the gate 23 controls the carrier flow between the source 22a and the drain 22b. The FET-based biosensor described herein provides a suitable biosensor for detecting the immobilization or adsorption of a biomolecule, for example, a nucleic acid, such as DNA, in an electrolyte solution, and enables label-free detection of the presence or absence of the biomolecule.

In one embodiment, an inorganic film is deposited on a surface of a gate allowing the FET-based biosensor according to the invention to be manufactured using a semiconductor fabrication process without performing any additional process. The inorganic film can be selectively deposited on designated areas, including particular gates selected from among a plurality of FETs, by patterning used in a semiconductor fabrication process. Selectively depositing the inorganic film enables one to avoid the attachment of a biomolecule to areas that cannot detect the biomolecule and to attach the biomolecule only to a surface of a desired gate among a plurality of gates. Therefore, the FET-based biosensor of the invention provides high detection sensitivity and can detect even trace amounts of a target biomolecule.

In one embodiment, the inorganic film comprises a metal oxide film or a metal hydroxide film. The metal oxide film can be Al₂O₃, TiO₂, or SnO₂, while the metal hydroxide film can be made of boehmite. The metal hydroxide film made of boehmite may be formed by thermally treating Al or Al₂O₃.

The biomolecule as used herein comprises a nucleic acid or a protein. As used herein, the term “nucleic acid” is meant to comprehend various nucleic acids, nucleic acid analogues, and hybrids thereof. A nucleic acid includes, for example, DNA, RNA, Peptide Nucleic Acid (PNA), Locked Nucleic Acid (LNA), or a hybrid thereof. In one embodiment, the nucleic acid can be an oligonucleotide or a Polymerase Chain Reaction (PCR) product.

In one embodiment, the thickness of the metal oxide film disposed on the surface of the gate is about 2 to about 30 nm, and the thickness of the metal hydroxide film is about 10 to about 150 nm. Further, the thickness of the inorganic film of the FET-based biosensor can be optionally adjusted to any desired thickness within the range of the Debye length. Thus, the thickness of the inorganic film can vary so long as the binding of the biomolecule to the inorganic film can occur within the Debye length, that is, within the detectable limit of the FET.

Referring again to FIG. 2, the gate 23 can include an oxide layer 24; a polysilicone layer 25 disposed on the oxide layer 24; and a gate electrode layer 26 disposed on the polysilicone layer 25. The gate electrode layer 26 can be made of any material. In an exemplary embodiment, the gate electrode layer 26 is gold.

In one embodiment, the invention provides a method of manufacturing the above-described FET-based biosensor. The method comprises exposing a surface of a gate electrode of a FET; and depositing an inorganic film on the exposed surface.

In one embodiment, a conventional semiconductor fabrication process can be applied to the method of manufacturing the FET-based biosensor according to the present invention.

For example, a method of manufacturing a FET-based biosensor including an inorganic film made of boehmite comprises exposing a gate electrode of a FET;

depositing Al or Al₂O₃ on the exposed surface of the gate electrode and on the remaining surface of the FET; etching the Al or Al₂O₃ deposited on the remaining surface of the FET; and contacting the Al or Al₂O₃ deposited on the exposed surface of the gate electrode with hot water to form boehmite.

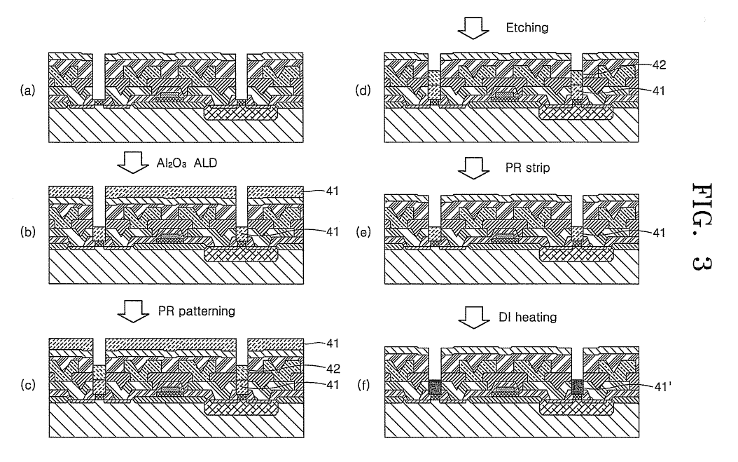

FIG. 3 is a schematic diagram showing the sequential processes for manufacturing a FET-based biosensor according to the invention.

Referring to (a) of FIG. 3, first, gate electrodes of a completed FET structure are exposed to the external environment. Generally, the entire surface of the FET structure is subjected to a passivation treatment to protect the FETs from ionic diffusion, etc. The exposure of the gate electrodes to the external environment may be performed by the deposition, exposure, and patterning of a typical photoresist (PR), etching using the PR as an etching mask, and removing the PR. Then, referring to (b) of FIG.3, an Al₂O₃ film 41 is deposited on the entire surface of the FET structure. The Al₂O₃ film 41 may be deposited to a thickness of 20Å or more by Atomic Layer Deposition (ALD). When Al is used instead of Al₂O₃, it may be deposited to a thickness of 10 nm or more by sputtering. Then, referring to (c) of FIG. 3, PR 42 is coated on only the surfaces of the gate electrodes by PR patterning.

Then, referring to (d) of FIG. 3, the Al₂O₃ film 41 formed on the surface of the FET structure other than the surfaces of the gate electrodes is removed by etching. Then, referring to (e) of FIG. 3, the PR 42 is removed from the surfaces of the gate electrodes. Then, the Al₂O₃ film 41 formed on the surfaces of the gate electrodes is treated with hot water to form boehmite 41′. The temperature of the hot water used to treat the Al₂O₃ film 41 can be about 90° to about 100° C., and the treatment time of the hot water can be about 3 to about 60 minutes.

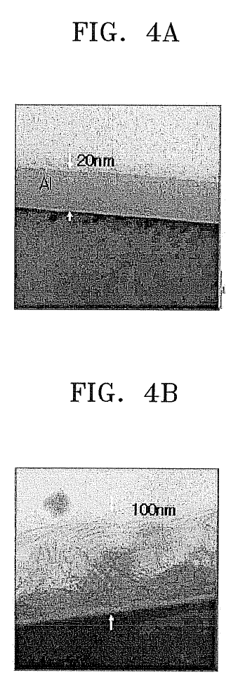

FIG. 4A is an image showing Al deposited on a surface of a gate in a FET-based biosensor according to the present invention, and FIG. 4B is an image showing porous boehmite produced when the Al surface of FIG. 4A is treated with hot water.

In one embodiment the invention provides a method of detecting the presence or concentration of a biomolecule using the above-described FET-based biosensor.

In an embodiment, the method of detecting the presence or concentration of the biomolecule comprises introducing the biomolecule to a surface of a gate of a FET-based biosensor, wherein an inorganic film capable of binding with the biomolecule is disposed on the surface of the gate; and measuring a current in a channel region between a source and a drain of the FET-based biosensor before and after introducing the biomolecule.

In an embodiment, the invention provides a method of detecting the presence or concentration of a biomolecule in a sample comprising performing PCR by providing a primer capable of binding with a target biomolecule in a sample suspected of containing the target biomolecule; introducing the sample to a surface of a gate of a FET-based biosensor wherein an inorganic film capable of binding with the target biomolecule is disposed on the surface of the gate; and measuring a current in a channel region between a source and a drain of the FET-based biosensor before and after introducing the sample to the surface of the gate.

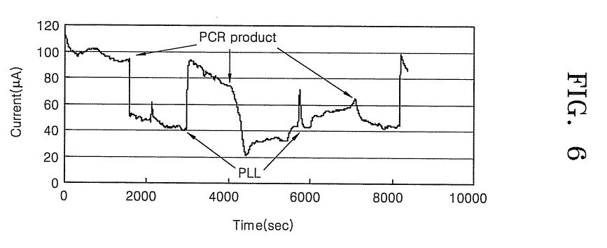

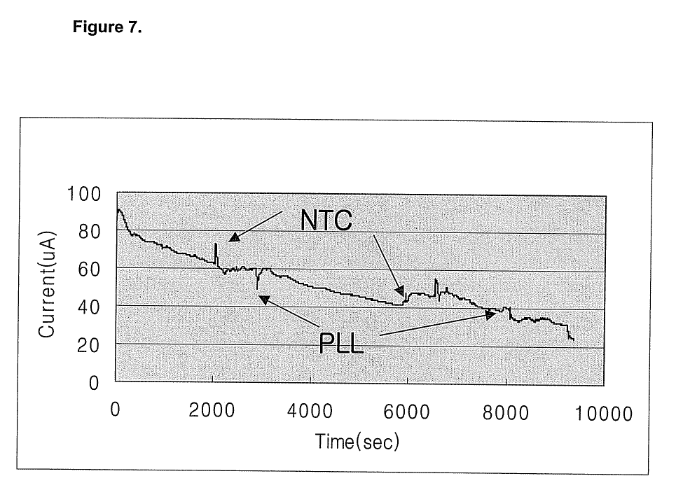

In one embodiment, the method of detecting the presence or concentration of the biomolecule using the FET-based biosensor can be used to detect a PCR product. Performing PCR on a sample suspected of containing the target biomolecule will amplify the target biomolecule, if the sample is present, and increase the likelihood of detecting the target biomolecule. Thus, if a target biomolecule is present in a sample, the target biomolecule can be amplified and a detectable amount of the PCR product can be obtained. On the other hand, if no target biomolecule is present in a sample, an amplified PCR product corresponding to the target biomolecule will not be obtained. Thus, the ability to detect the presence or concentration of a target biomolecule in a sample can be determined by detecting the presence or absence, or the concentration if present, of a PCR product. For reference, Example 4 demonstrates a case where a PCR product is obtained due to the presence of a target biomolecule in a sample, following PCR amplification of the sample using primers capable of binding with a target biomolecule. Example 5 demonstrate a case where a PCR product is not obtained following PCR amplification of the sample using primers capable of binding with a target biomolecule, due to the absence of a target biomolecule in the sample. The results of Examples 4 and 5 show that the presence or absence of a target biomolecule in a sample can be efficiently detected by the FET-based biosensor in conjunction with PCR amplification (see FIGS. 6 and 7).

The invention will now be described in more detail with reference to the following Examples. The following Examples are for illustrative purposes and are not intended to limit the scope of the present invention.

### Example 1

### Manufacturing of FET-Based Biosensors According to the Present Invention

FET devices were manufactured using an XC10-1.0 um CMOS process in semiconductor fabrication facilities (X-FAB Semiconductor Foundries, Germany). The standard CMOS process differs slightly among manufacturing companies, but these differences do not affect the FET device characteristics and are irrelevant to the present invention. FET-based biosensors according to the invention were manufactured using FET devices as illustrated in the manufacturing method schematically shown in FIG. 3.

First, the passivation layer of the FET structure was removed, and the gate electrodes were exposed (see (a) of FIG. 3). This process was performed by X-FAB. Then, a surface of the FET structure, including the exposed gate electrodes, was carefully washed and dried. The surface of the FET structure was washed with pure acetone and water using a wet station used in semiconductor fabrication. The FET structure was subsequently dried using a spin drier.

Next, Al₂O₃ was deposited on the entire surface of the FET structure by ALD to a thickness of 20 nm (see (b) of FIG. 3). Then, PR was coated on only surfaces of the gate electrodes by PR patterning (see (c) of FIG. 3). Then, the Al₂O₃ present on the surface of the FET structure, other than the surfaces of the gate electrodes, was removed by etching (see (d) of FIG. 3). The PR present on the surfaces of the gate electrodes was then stripped (see (e) of FIG. 3). Then, Al₂O₃ present on the surfaces of the gate electrodes was treated with hot water at a temperature of 90° C., for 5 or 30 minutes to produce boehmite.

For the FET-based biosensor produced according to the procedure described above, the surface resistance of Al₂O₃ was 0.7 MΩ , and the surface resistance of boehmite was 0.36 MΩ (following a hot water treatment for 5 minutes) and 0.24 MΩ (following a hot water treatment for 30 minutes).

### Example 2

### Manufacturing of FET-Based Biosensors According to the Present Invention

For this example, the FET-based biosensors were manufactured in the same manner as described in Example 1, except that Al was deposited to a thickness of 20 nm by sputtering, instead of the deposition of Al₂O₃ by ALD.

FIG. 4A is an image showing Al deposited on surfaces of gates in the FET-based biosensors manufactured in Example 2, and FIG. 4B is an image showing porous boehmite produced when Al of FIG. 4A is treated with hot water. Referring to FIG. 4B, boehmite was formed to a thickness of 100 nm, and the Al film was mostly converted to the porous boehmite structure.

For the FET-based biosensor produced according to the procedure described above, the surface resistance of Al was 6.0 MΩ and the surface resistance of boehmite was 0.25 Ω (following treatment with hot water for 5 minutes) and 0.33 MΩ (following treatment with hot water for 30 minutes).

### Example 3

### Detection of Oligonucleotides Using FET-Based Biosensors According to the Present Invention

The FET-based biosensors manufactured in Example 1 were connected to a parameter analyzer and stabilized. Stabilization of the FET-based biosensors was performed by submerging the FET devices in a 0.1×phosphate buffered saline (PBS) solution while iteratively changing the gate voltage. The gate voltage was then set to 2 V.

At a predetermined time after the FET devices were stabilized, 25 bp probe oligonucleotides were exposed to the FET-based biosensors. The probe oligonucleotides consisted of a nucleotide sequence of 5′-(GTG TGA GAG TGG AAA GTT CAC ACT G)-3′ (SEQ ID NO: 1), and were used at a concentration of 1 ng/μl. At a predetermined time after the probe oligonucleotides were exposed to the FET-based biosensors, 2 ng/μlμl of PLL was introduced. The oligonucleotides and PLL solutions were each made with 0.01 mM PBS solution (pH 7).

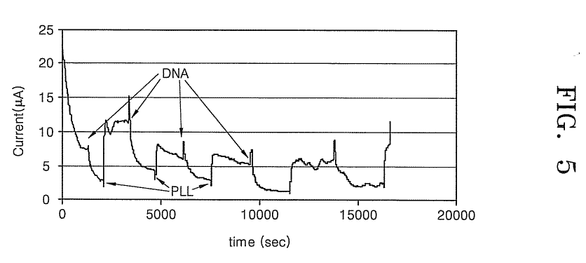

FIG. 5 is a graph illustrating the change in current when the oligonucleotides and the PLL were alternately loaded onto the surfaces of the gate electrodes in the FET-based biosensors of Example 1.

Referring to FIG. 5, at an initial stage of the introduction of the probe oligonucleotides to the FET-based biosensors, the current was considerably reduced by about 5 μA (from 7 μA (before the incorporation) to 2 μA (after the incorporation)). This result shows that the target biomolecule (i.e., oligonucleotide) can bind to the inorganic film deposited on the surface of the gate of the FET-based biosensor according to the invention, and thus, the presence or concentration of the target sample can be effectively detected. On the other hand, when the positively charged PLL was introduced to the FET-based biosensors, the current rapidly increased. When the negatively charged oligonucleotides were again introduced into the FET-based biosensors, the current was rapidly reduced. These results demonstrate that even when the distance from the gate surface increases by continuous incorporation of oligonucleotide and PLL, the oligonucleotide can be effectively detected.

### Example 4

### Detection of PCR Products Using FET-Based Biosensors According to the Present Invention

The FET-based biosensors manufactured in Example 1 were connected to a parameter analyzer and stabilized. Stabilization of the FET-based biosensors was performed by submerging the FET devices in a 0.1×PBS solution while iteratively changing the gate voltage. The gate voltage was then set to 2 V.

At a predetermined time after the FET devices were stabilized, PCR products were exposed to the FET-based biosensors. The PCR products were obtained by PCR using Staphylococcus aureus bacterial DNA as a template. Forward and reverse primers consisting of nucleotide sequences of 5′-(TAG CAT ATC AGA AGG CAC ACC C)-3′ (SEQ ID NO: 2) and 5′-(ATC CAC TCA AGA GAG ACA ACA TT)-3′ (SEQ ID NO: 3), respectively, were used to amplify the PCR products. The length and concentration of the PCR products were 240 bp and 5 ng/μl, respectively. At a predetermined time after the introduction of the PCR products, 2 ng/μl μl of PLL was introduced to the FET-based biosensors. The solutions of the PCR products and the PLL were made with 0.01 mM PBS solution (pH 7).

FIG. 6 is a graph showing the change in current when the PCR products and the PLL were alternately exposed to the surfaces of the gates in the FET-based biosensors manufactured in Example 1. The graph shows the average of the results of 192 PCR arrays.

Referring to FIG. 6, at an initial stage of the incorporation of the PCR products, the current was considerably reduced by about 40 μA (from 92 μA (before the incorporation) to 52 μA (after the incorporation)). This result demonstrates that a target biomolecule (i.e., PCR product) can bind to the inorganic film deposited on the surface of the gate of a FET-based biosensor according to the invention, and thus, the presence or concentration of the target biomolecule can be effectively detected. On the other hand, when the positively charged PLL was incorporated into the FET-based biosensors, the current rapidly increased. When the negatively charged PCR products were again incorporated into the FET-based biosensors, the current was rapidly reduced. This result demonstrates that even when the distance from the gate surface increases by continuous incorporation of the PCR product and PLL, the PCR product can be effectively detected.

### Example 5

### Detection of Non-Template Control (NTC, Negative Control) Products Using FET-Based Biosensors According to the Present Invention

The FET-based biosensors manufactured in Example 1 were connected to a parameter analyzer and stabilized. Stabilization of the FET-based biosensors was performed by submerging the FET devices in a 0.1×PBS solution while iteratively changing the gate voltage. The gate voltage was then set to 2 V.

At a predetermined time after the FET devices were stabilized, an NTC solution was introduced to the gates of the FET-based biosensors by injection. The NTC solution excluded a template biomolecule to confirm possible contamination during PCR. PCR was performed in the same manner as in Example 4 except that no template biomolecule was present in the sample. Thus, PCR amplification could not occur. This experiment was intended to demonstrate the results obtained for a situation in which PCR amplification of a product does not occur due to the absence of target DNA molecules in the sample. At a predetermined time after the exposure of the NTC solution to the FET-based biosensors, 2 ng/μl of PLL was introduced. The NTC solution and the PLL solution were made with 0.01 mM PBS solution (pH 7).

FIG. 7 is a graph showing the change in current when the NTC solution and the PLL were alternately loaded onto the surfaces of the gates in the FET-based biosensors manufactured in Example 1. The graph shows the average of the results of 192 PCR arrays.

Referring to FIG. 7, when the NTC solution was injected, a small change in current was observed. This change was determined to be the signal noise due to the injection of the sample. From these results, it can be seen that when a target DNA is not present in a PCR sample, and a PCR product cannot be obtained, no signal from DNA can be detected using the FET-based biosensors. It can also be seen that since the binding of negatively charged DNA to a gate surface does not occur at an initial stage, the binding of PLL to the gate surface does not occur as well.

As described above, a FET-based biosensor including an inorganic film according to the invention can be manufactured using a semiconductor fabrication process without performing any additional process steps. Therefore, the inorganic film can be selectively deposited on a surface of a specific gate of a single FET or on the surfaces of some gates of a plurality of FETs using patterning. Furthermore, even trace amounts of a target biomolecule can be effectively detected. In addition, since the inorganic film can be formed to a very thin thickness, the binding of a biomolecule to the inorganic film can be detected within the detectable limit (Debye length) of a FET.

The terminology used herein is for the purpose of describing particular embodiments only and is not intended to be limiting of the invention. The terms “a” and “an” do not denote a limitation of quantity, but rather denote the presence of at least one of the referenced item. The term “or” means “and/or”. The terms “comprising”, “having”, “including”, and “containing” are to be construed as open-ended terms (i.e., meaning “including, but not limited to”).

Recitation of ranges of values are merely intended to serve as a shorthand method of referring individually to each separate value falling within the range, unless otherwise indicated herein, and each separate value is incorporated into the specification as if it were individually recited herein. The endpoints of all ranges are included within the range and independently combinable.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein. Unless defined otherwise, technical and scientific terms used herein have the same meaning as is commonly understood by one of skill in the art to which this invention belongs.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context. While the invention has been particularly shown and described with reference to exemplary embodiments thereof, it will be understood by those of ordinary skill in the art that various changes in form and details may be made therein without departing from the spirit and scope of the present invention as defined by the following claims. Thus, the embodiments must be employed for descriptive purposes, not for restrictive purposes. The scope of the present invention is defined by the following claims, not by the above descriptions. Thus, it must be understood that the present invention covers equivalents, alternatives, etc. falling within the scope of the present invention.

What is claimed is:

1. A Field-Effect Transistor (FET)-based biosensor comprising:
a substrate;
a source and a drain,
wherein the source and the drain are disposed on separated regions of the substrate, wherein polarity of the source and the drain is opposite to polarity of the substrate;
a gate, disposed on the substrate, wherein the gate contacts the source and the drain; and
an inorganic film disposed on a surface of the gate, wherein the inorganic film is capable of binding with a biomolecule.

2. The FET-based biosensor of claim 1, wherein the inorganic film comprises a metal oxide film or a metal hydroxide film.

3. The FET-based biosensor of claim 2, wherein the metal oxide film comprises a metal oxide selected from the group consisting of Al₂O₃, TiO₂, and SnO₂.

4. The FET-based biosensor of claim 2, wherein the metal hydroxide film comprises boehmite.

5. The FET-based biosensor of claim 1, wherein the biomolecule comprises a nucleic acid or a protein.

6. The FET-based biosensor of claim 5, wherein the nucleic acid is selected from the group consisting of DNA, RNA, Peptide Nucleic Acid (PNA), Locked Nucleic Acid (LNA), and a hybrid thereof.

7. The FET-based biosensor of claim 5, wherein the nucleic acid is an oligonucleotide or a Polymerase Chain Reaction (PCR) product.

8. The FET-based biosensor of claim 1, wherein the substrate is doped with n-type, and the source and the drain are doped with p-type.

9. The FET-based biosensor of claim 1, wherein the gate comprises:
an oxide layer;
a polysilicone layer disposed on the oxide layer; and
a gate electrode layer disposed on the polysilicone layer.

10. A method of manufacturing a Field-Effect Transistor (FET)-based biosensor, the method comprising:
exposing a surface of a gate electrode of a FET; and
depositing an inorganic film on the exposed surface

11. The method of claim 10, wherein depositing the inorganic film on the exposed surface comprises:
depositing a film of Al or Al₂O₃ on the exposed surface of the gate electrode and on a remaining surface of the FET;
etching the film of Al or Al₂O₃ deposited on the remaining surface of the FET; and
contacting the film of Al or Al₂O₃ deposited on the exposed surface of the gate electrode with hot water to form boehmite.

12. The method of claim 11, wherein Al₂O₃ is deposited on the exposed surface of the gate electrode and on the remaining surface of the FET to a thickness of about 2 to about 30 nm by atomic layer deposition.

13. The method of claim 11, wherein the temperature of the hot water is about 90 to about 100° C.

14. A method of detecting a biomolecule, the method comprising:
Introducing a biomolecule to a surface of a gate of a Field-Effect Transistor (FET)-based biosensor, wherein an inorganic film capable of binding with the biomolecule is disposed on the surface of the gate; and
measuring a current in a channel region between a source and a drain of the FET-based biosensor before and after introducing the biomolecule.

15. The method of claim 14, wherein the biomolecule is a nucleic acid or a protein.

16. The method of claim 15, wherein the nucleic acid is an oligonucleotide or a PCR product.

17. The method of claim 14, wherein the inorganic film comprises a metal oxide film or a metal hydroxide film.

18. The method of claim 17, wherein the metal oxide film comprises a metal oxide selected from the group consisting of Al₂O₃, TiO₂, and SnO₂.

19. The method of claim 17, wherein the metal hydroxide film comprises boehmite.


SEQUENCE LISTING (3 sequences)

SEQ ID NO: 1 - DNA, 25 bp, Artificial Sequence
  probe
gtgtgagagtggaaagttcacactg

SEQ ID NO: 2 - DNA, 22 bp, Artificial Sequence
  forward primer
tagcatatcagaaggcacaccc

SEQ ID NO: 3 - DNA, 23 bp, Artificial Sequence
  reverse primer
atccactcaagagagacaacatt